(19) United States
(12) Patent Application Publication
(10) Pub. No.: US 2025/0280703 A1
(43) Pub. Date: Sep. 4, 2025

(54) DISPLAY PANEL AND DISPLAY APPARATUS

(71) Applicants: Hefei Visionox Technology Co., Ltd., Hefei (CN); Visionox Technology Inc., Suzhou (CN)

(72) Inventors: Xuejing ZHU, Hefei (CN); Xiaoxi SUN, Hefei (CN); Yuan YAO, Hefei (CN); Qing BAI, Hefei (CN); Yongqiang DU, Hefei (CN); Shizhen FENG, Hefei (CN)

(73) Assignees: Hefei Visionox Technology Co., Ltd., Hefei (CN); Visionox Technology Inc., Suzhou (CN)

(21) Appl. No.: 18/750,158

(22) Filed: Jun. 21, 2024

(30) Foreign Application Priority Data
Feb. 29, 2024 (CN) 202410233003.3

(51) Int. Cl. H10K 59/80; H10K 59/131

(52) U.S. Cl. CPC H10K 59/873; H10K 59/131

(57) ABSTRACT

A display panel and a display apparatus, the display panel includes: a base plate; at least a dam provided on a side of the base plate and including a first organic layer; and an inorganic layer provided on a side of the dam away from the base plate and in contact with and connected to the first organic layer. The inorganic layer is provided with a first via extending through the inorganic layer, and an orthographic projection of the first via on the base plate is located within an orthographic projection of the dam on the base plate. The inorganic layer is provided with the first via, and the orthographic projection of the first via on the base plate is located within the orthographic projection of the dam on the base plate.

### CROSS REFERENCE TO RELATED APPLICATION

The present application claims priority to Chinese Patent Application No. 202410233003.3 filed on Feb. 29, 2024, and titled “DISPLAY PANEL AND DISPLAY APPARATUS”, which is incorporated herein by reference in its entirety.

### TECHNICAL FIELD

The present application relates to the technical field of display devices, and particularly to a display panel and a display apparatus.

### BACKGROUND

Organic Light-Emitting Diode (OLED) displays is also known as organic electroluminescent displays. Compared to the existing liquid crystal displays, OLED displays have a set of advantages such as self-luminescence, wide viewing angle, ultra-lightness, ultra-thinness, high brightness, low power consumption and fast response, and the response speed of the OLED displays may be 1000 times of that of the liquid crystal displays. Accordingly, OLED has become a very popular flat panel display product at home and abroad, and has a broad application prospect.

However, the process performance of the display panels needs to be improved.

### SUMMARY

Embodiments of the present application provide a display panel and a display apparatus, which is aimed at improving the process performance of the display panel.

Embodiments of a first aspect of the present application provide a display panel including: a base plate; at least a dam provided on a side of the base plate and including a first organic layer; and an inorganic layer provided on a side of the dam away from the base plate and in contact with and connected to the first organic layer, wherein the inorganic layer is provided with a first via extending through the inorganic layer, and an orthographic projection of the first via on the base plate overlaps an orthographic projection of the first organic layer on the base plate.

The first aspect of the present application further provides a display panel having a display region and a non-display region provided around at least a part of the display region, and the display panel includes: a base plate; a dam provided on a side of the base plate and provided around the display region in the non-display region, wherein the dam includes a first organic layer; and an inorganic layer provided on a side of the dam away from the base plate, wherein the inorganic layer is provided with a first via extending through the inorganic layer, and the first via exposes at least a part of a region of the first organic layer.

The first aspect of the present application further provides a display panel having a display region and a non-display region provided around at least a part of the display region, and the display panel includes: a base plate; a dam provided on the base plate and provided around the display region in the non-display region, wherein the dam includes a first organic layer; and a pixel definition layer provided on the base plate and including a pixel definition portion located in the display region and a contact portion located in the non-display region, wherein the pixel definition portion is provided with a plurality of pixel openings; wherein at least a part of the contact portion covers the dam, the contact portion is provided with a first via, and an orthographic projection of the first via on the base plate overlaps an orthographic projection of the first organic layer on the base plate.

Embodiments of a second aspect of the present application provide a display apparatus including the display panel according to any of the embodiments of the first aspect.

In the display panel according to the embodiments of the present application, the display panel includes the base plate, the dam, and the inorganic layer. The dam includes the first organic layer, and in the manufacturing process of the first organic layer, the first organic layer may release oxygen elements to form gas. The inorganic layer has a desired hermetic property, and gas flowing between the inorganic layer and the first organic layer may cause film layer peeling-off. The inorganic layer is provided with the first via, and the orthographic projection of the first via on the base plate overlaps the orthographic projection of the first organic layer on the base plate, that is, gas generated in the first organic layer may flow out of the first via, so that a phenomenon of film layer peeling-off caused by the gas remaining between the first organic layer and the inorganic layer is reduced, thereby improving the process performance of the display panel.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numerals represent the same or similar features.

FIG. 1 is a schematic structural view of a display panel according to an embodiment of the present application;

FIG. 2 is a partial enlarged schematic structural diagram at P in FIG. 1;

FIG. 3 is a cross-sectional view at A-A in FIG. 2;

FIG. 4 is a partial enlarged schematic structural view of FIG. 3;

FIG. 5 is s a cross-sectional view at B-B in FIG. 2;

FIG. 6 is a cross-sectional view at C-C in FIG. 2;

FIG. 7 is a schematic structural view of a display panel according to another embodiment of the present application.

Reference Numerals:
100: Base plate; 110: Dam; 111: First organic layer; 120: First conductive line; 121: Second via; 130: Cushion layer; 140: Planarization layer;
200: Inorganic layer; 210: Pixel definition portion; 220: Contact portion; 230: Pixel opening; 240: First via; 241: First sub-via; 242: Second sub-via;
300: Light-emitting layer; 310: Light-emitting unit;
400: Encapsulation layer; 410: First encapsulation layer; 411: Encapsulation portion; 420: Second encapsulation layer; 430: Third encapsulation layer;
500: Isolation structure; 510: Isolation opening; 520: First layer; 530: Second layer; 540: Third layer;
700: First electrode layer; 710: First electrode;
800: Second electrode layer; 810: Second electrode;
AA: Display region; NA: Non-display region.

### DETAILED DESCRIPTION

Features and exemplary embodiments of various aspects of the present application will be described in detail below. Numerous specific details are set forth in the following detailed description to provide a thorough understanding of the present application. However, it will be apparent to a person skilled in the art that the present application may be practiced without some of these specific details. The following description of the embodiments is merely intended to provide a better understanding of the present application by illustrating examples of the present application. In the accompanying drawings and the following description, at least some of well-known structures and techniques are not shown so as to avoid unnecessary obscurity of the present application. In addition, size of some structures may be exaggerated for clarity. Furthermore, the features, structures, or characteristics described below may be combined in one or more embodiments by any suitable manner.

In the description of the present application, it should be noted that, unless otherwise specified, the term “a plurality of” indicates two or more; the terms “upper”, “lower”, “left”, “right”, “inner”, “outer”, and the like indicate orientations or positional relationships for facilitating and simplifying description of the present application, and do not indicate or imply that the involved devices or elements must have such a particular orientation, or must be constructed and operated in such a particular orientation, and thus should not be construed to limit the present application. In addition, the terms “first”, “second”, and the like are merely used for the purpose of description and should not be interpreted to indicate or imply relative importance.

The directional words appearing in the following description indicate directions shown in the drawings and do not limit the specific structure in the embodiments of the present application. In the description of the present application, it should be further noted that, unless otherwise clearly specified and limited, the terms “installation” and “connection” should be understood in a broad sense, for example, the “connection” may refer to a fixed, a detachable or an integrated connection; and it may refer to a director an indirect connection. For a person skilled in the art, the specific meaning of the terms mentioned above in the present application may be understood in accordance with specific situations.

In a display panel according to the related art, the display panel includes a base plate and a dam provided on the base plate. The dam relatively is high. Other film layers may further be provided on the dam, and the applicant has found that a problem of peeling-off easily occurs between the dam and the other film layers. Further studies by the applicant have found that this is because an organic film layer is generally provided in the dam, and the dam is formed by stacking organic film layers, but an inorganic film layer is generally provided on the dam, and the inorganic film layer has a desired hermetic property. Under a condition that the organic film layer generates gas in the manufacturing process, the gas flows between the inorganic film layer and the organic film layer, thereby causing the problem of peeling-off between the inorganic film layer and the dam.

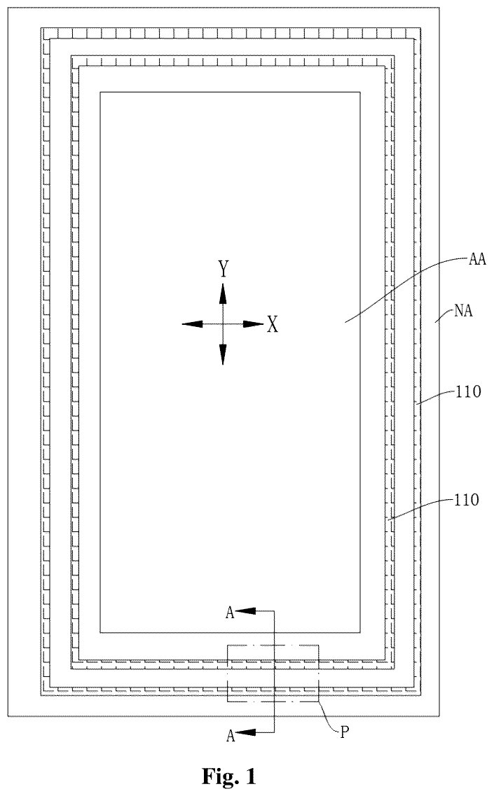

The present application is set forth to reduce the above technical problem. For a better understanding of the present application, a display panel and a display apparatus according to embodiments of the present application will be described in detail below with reference to FIG. 1 to FIG. 7.

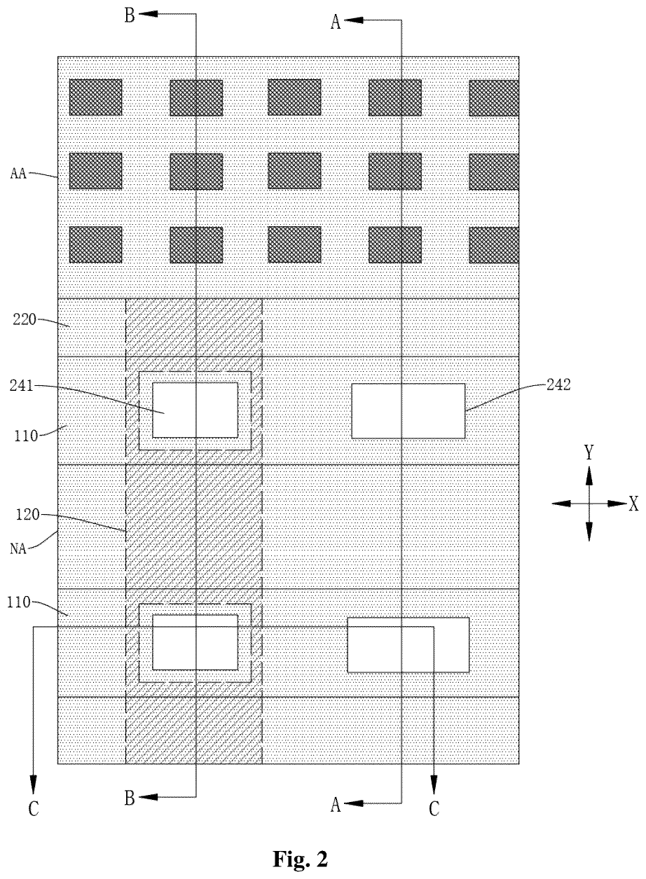

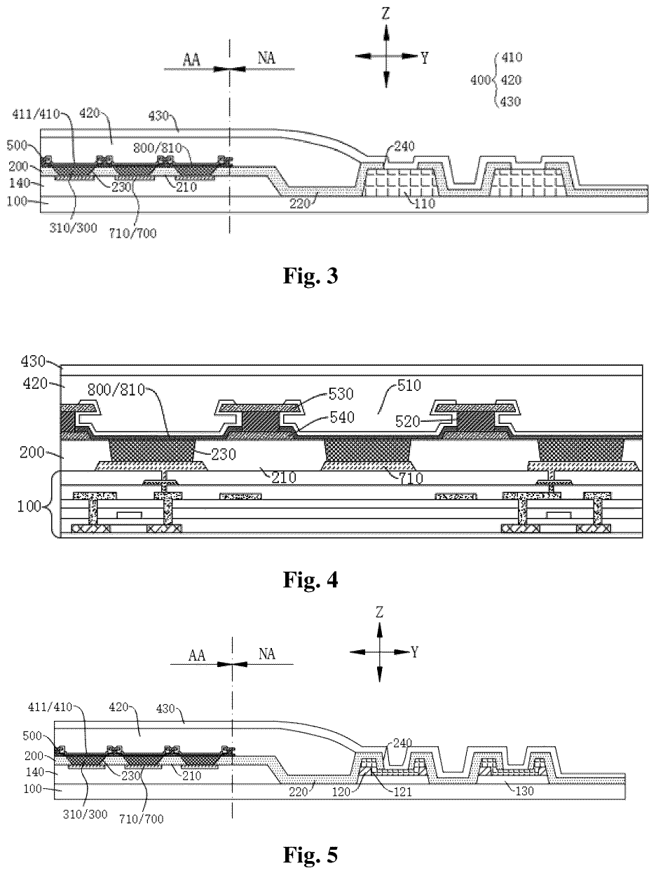

FIG. 1 is a schematic structural view of a display panel according to an embodiment of the present application, FIG. 2 is a partial enlarged schematic structural diagram at P in FIG. 1, FIG. 3 is a cross-sectional view at A-A in FIG. 1, and FIG. 4 is a partial enlarged schematic structural view of FIG. 3.

As shown in FIG. 1 to FIG. 4, embodiments of a first aspect of the present application provide a display panel including: a base plate 100; at least a dam 110 provided on a side of the base plate 100 and including a first organic layer 111; and an inorganic layer 200 provided on a side of the dam 110 away from the base plate 100 and in contact with and connected to the first organic layer 111, in which the inorganic layer 200 is provided with a first via 240 extending through the inorganic layer 200, and an orthographic projection of the first via 240 on the base plate 100 overlaps an orthographic projection of the first organic layer 111 on the base plate 100.

In the display panel according to the embodiments of the present application, the display panel includes the base plate 100, the dam 110, and the inorganic layer 200. The dam 110 includes the first organic layer 111, and in the manufacturing process of the first organic layer 111, the first organic layer 111 may release oxygen elements to form gas. The inorganic layer 200 has a desired hermetic property, and gas flowing between the inorganic layer 200 and the first organic layer 111 may cause film layer peeling-off. The inorganic layer 200 is provided with the first via 240, and the orthographic projection of the first via 240 on the base plate 100 overlaps the orthographic projection of the first organic layer 111 on the base plate 100, that is, gas generated in the first organic layer 111 may flow out of the first via 240, so that a phenomenon of film layer peeling-off caused by the gas remaining between the first organic layer 111 and the inorganic layer 200 is reduced, thereby improving the process performance of the display panel.

Optionally, the orthographic projection of the first via 240 on the base plate 100 is located within the orthographic projection of the first organic layer 111 on the base plate 100, so that more gas can flow out of the first via 240.

The base plate 100 may be provided in various manners, and the base plate 100 may include a substrate, and a first conductive layer, a second conductive layer, and a third conductive layer which are provided on a side of the substrate and are stacked. An insulation layer is provided between adjacent conductive layers. In an example, a pixel driving circuit is provided within the base plate 100 and includes a transistor and a storage capacitor. The transistor includes a semiconductor, a gate, a source, and a drain. The storage capacitor includes a first electrode plate and a second electrode plate. As an example, the gate and the first electrode plate may be located in the first conductive layer, the second electrode plate may be located in the second conductive layer, and the source and the drain may be located in the third conductive layer.

Optionally, the base plate 100 includes a planarization layer 140, and a material of the planarization layer 140 includes an organic material.

Optionally, the first organic layer 111 within the dam 110 and the planarization layer 140 may be provided on the same layer and made of the same material. That is, under a condition that the planarization layer 140 is manufactured, an organic material at a location where the dam 110 is located may be retained to form the dam 110, so that a height of the dam 110 is increased, and the manufacturing process of the display panel is simplified.

Optionally, the base plate 100 further includes a plurality of conductive layers, an insulation layer is provided between the plurality of conductive layers, and under a condition that the insulation layer is manufactured, materials in a part of dams 110 may be retained to form the first organic layer 111, that is, the insulation layer and the first organic layer 111 are provided on the same layer and made of the same material.

Optionally, a material of the first organic layer 111 includes an organic material. The first organic layer 111 may have a relatively great thickness to ensure that the dam 110 has a relatively great height.

In some optional embodiments, the orthographic projection of the first via 240 on the base plate 100 is located within the orthographic projection of the first organic layer 111 on the base plate 100. Accordingly, the gas generated by the first organic layer 111 can flow out of the first via 240 more quickly.

The display panel may include one or more first vias 240, and a plurality of the first vias 240 may be provided at intervals along an extension direction of the dam 110. By providing the plurality of the first vias 240, gas at different locations within the organic layer can be released, and a problem of film layer peeling-off that occurs easily between the organic layer and the contact portion 220 is further reduced.

Optionally, the display panel may include one dam 110, and the one dam 110 may be in a closed ring shape around the display region AA. Optionally, an extension direction of the dam 110 may be a direction along which the dam 110 extends around the display region AA. For example, under a condition that segments of the dam 110 located on two sides of the display region AA along a first direction extend along a second direction, an extension direction of a part of the dams 110 located on two sides of the display region AA along the first direction is the second direction. Under a condition that segments of the dam 110 located on two sides of the display region AA along a second direction extend along a first direction, an extension direction of a part of the dams 110 located on two sides of the display region AA along the second direction is the first direction.

Optionally, the display may include two or more dams 110 nested with each other. Each of the dams 110 is provided with a corresponding first via 240, that is, each of the dams 110 is provided with a corresponding first via 240 above the organic layer, so that the problem of film layer peeling-off that occurs easily between the organic layer and the contact portion 220 is further reduced.

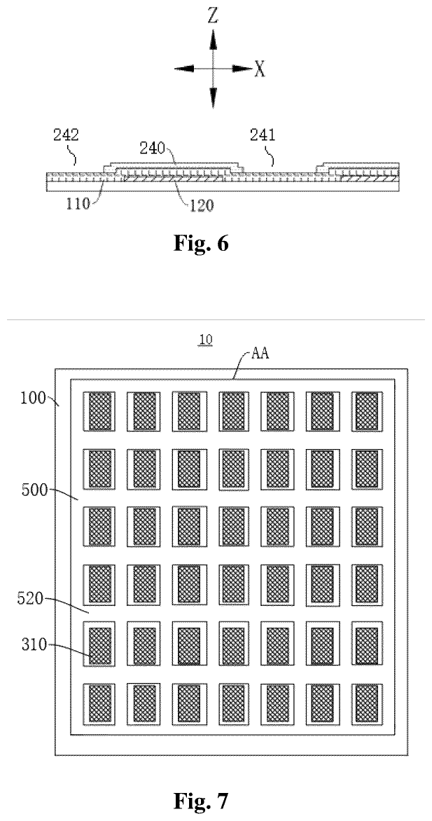

In some optional embodiments, as shown in FIG. 5 and FIG. 6, a first conductive line 120 is provided on a side of the first organic layer 111 facing to the base plate 100, the first conductive line 120 is provided with a second via 121 extending through the first conductive line 120, the first via 121 includes a first sub-via 241, and an orthographic projection of the first sub-via 241 on the base plate 100 at least partially overlaps an orthographic projection of the second via 121 on the base plate 100. Accordingly, the inorganic layer 200 may cover at least a part of an inner wall surface of the first conductive line 120 facing to the second via 121.

Optionally, the orthographic projection of the first sub-via 241 on the base plate 100 is located within the orthographic projection of the second via 121 on the base plate 100.

In these optional embodiments, the first conductive line 120 is further provided with the second via 121, the orthographic projection of the first sub-via 241 on the base plate 100 is located within the orthographic projection of the second via 121 on the base plate 100, that is, a size of the first sub-via 241 is less than a size of the second via 121, and a part of the inorganic layer 200 may extend into the second via 121 to wrap the inner wall surface of the first conductive line 120 facing to the second via 121, so that the inorganic layer 200 may provide protection for the first conductive line 120.

Optionally, the display panel has a display region AA and a non-display region NA provided around the display region AA, and the dam 110 may be provided in the non-display region NA and provided around the display region AA. The first conductive line 120 may intersect the dam 110 along a direction from the display region AA to the non-display region NA, or the first conductive line 120 may be provided in parallel with a part of the dam 110.

Optionally, the first conductive line 120 may be a power signal line. For example, the first conductive line 120 is configured to transmit a low-level voltage signal ELVSS, or the first conductive line 120 is configured to transmit a driving power supply voltage signal ELVDD.

Optionally, the first conductive line 120 may be provided as a single film layer, or the first conductive line 120 may include a plurality of stacked conductive layers. For example, the first conductive line 120 includes a first sub-layer and a second sub-layer that are stacked, the second sub-layer is located on a side of the first sub-layer away from the base plate 100, a material of the first sub-layer may be aluminium, and a material of the second sub-layer may be titanium. Optionally, the first conductive line 120 may further include a third sub-layer located on a side of the first sub-layer away from the second sub-layer, and a material of the third sub-layer may include titanium.

Optionally, a cushion layer 130 is provided on a side of the first conductive line 120 facing to the base plate 100, and a material of the cushion layer 130 may include an organic material. In the manufacturing process, since the organic material has desired fluidity, the first organic layer 111 above the first conductive line 120 tends to be relatively thin. In the etching process of the inorganic layer 200, etching gas contains elemental oxygen gas, and the elemental oxygen gas may etch away the relatively thin organic layer 111, leaving the second sub-layer exposed. The etching gas may contain elemental fluorine gas, and the elemental fluorine gas may react with the titanium to cause damage to the second sub-layer, possibly resulting in an exposed first sub-layer. Under a condition that the material of the first sub-layer includes aluminum, the aluminum may react with the oxygen element to form a greater volume of aluminum oxide, thereby causing separation of the film layers and resulting in encapsulation degradation.

In the embodiments of the present application, although the first conductive line 120 is provided with the second via 121, the inorganic layer 200 may cover the inner wall surface of the first conductive line 120 facing to the second via 121, that is, a region where the first conductive line 120 exists is covered by the contact portion 220, so that the probability of the first conductive line 120 being etched and deformed or reacting with the oxygen element may be reduced, thereby further improving the encapsulation yield.

Numbers of the first sub-vias 241 and the second vias 121 are various, for example, the display panel may include one first sub-via 241 and one second via 121. Optionally, in some other embodiments, the display panel may include a plurality of the first sub-vias 241 and a plurality of the second vias 121, and an orthographic projection of each of the first sub-vias 241 on the base plate 100 is located within an orthographic projection of a corresponding second via 121 on the base plate 100. Accordingly, the inorganic layer 200 provides better protection for the first conductive line 120.

Optionally, under a condition that the display panel includes the plurality of the first sub-vias 241, the plurality of the first sub-vias 241 may be provided at intervals along the extension direction of the dam 110, so that gas generated by first organic layers 111 at different locations can flow out through the first sub-vias 241.

In some optional embodiments, the first via 240 further includes a second sub-via 242, an orthographic projection of the second sub-via 242 on the base plate 100 is located outside an orthographic projection of the first conductive line 120 on the base plate 100, and an area of the orthographic projection of the second sub-via 242 on the base plate 100 is greater than an area of the orthographic projection of the first sub-via 241 on the base plate 100.

In these optional embodiments, the first via 240 may further include a second sub-via 242 that does not overlap the first conductive line 120, a size of the second sub-via 242 is greater than a size of the first sub-via 241, that is, the size of the first sub-via 241 is relatively small, so that the inorganic layer 200 may better cover the first conductive line 120. The relatively great size of the second sub-via 242 can increase a rate at which the gas generated in the first organic layer 111 flows out of the inorganic layer 200, and further reduce a problem of peeling-off caused easily between the inorganic layer 200 and the first organic layer 111.

Optionally, the display panel may only include the second sub-via 242, and does not include the first sub-via 241.

As described above, the display panel includes the display region AA and the non-display region NA, the dam 110 is located in the non-display region NA, the inorganic layer 200 includes a pixel definition portion 210 located in the display region AA and the contact portion 220 located in the non-display region NA, the contact portion 220 is provided with the first via 240, and the pixel definition portion 210 is provided with a plurality of pixel openings 230.

In these optional embodiments, the pixel definition portion 210 is provided on the same layer as the contact portion 220, that is, a film layer provided with the first via 240 is provided on the same layer as a film layer provided with the pixel opening 230, and under a condition that the pixel definition layer is manufactured, a part of the material may be retained to cover the dam 110, so that the manufacturing process of the display panel can be simplified and the manufacturing efficiency of the display panel can be improved.

In these optional embodiments, the non-display region NA includes a lower frame, and the first via 240 is provided at least in the lower frame.

Optionally, the display panel further includes a light-emitting layer 300, and the light-emitting layer 300 includes a light-emitting unit 310 located within the pixel opening 230 to achieve light-emitting and display of the display panel.

In some optional embodiments, as shown in FIG. 5 to FIG. 7, the display panel further includes an isolation structure 500 provided on the base plate 100, and an isolation opening 510 surrounded by the isolation structure 500, and an orthographic projection of the isolation opening 510 on the base plate 100 at least partially overlaps an orthographic projection of the pixel opening 230 on the base plate 100.

In these optional embodiments, by providing the isolation structure 500, the light-emitting material can be divided into a plurality of light-emitting units 310 which are independent from each other and each located in a corresponding isolation opening 510, so that an evaporation process of the fine mask is omitted, and the manufacturing process of the display panel is simplified. The orthographic projection of the isolation opening 510 on the base plate 100 at least partially overlaps the orthographic projection of the pixel opening 230 on the base plate 100, so that the light-emitting unit 310 can be located within both the isolation opening 510 and the pixel opening 230.

Optionally, the orthographic projection of the pixel opening 230 on the base plate 100 is located within the orthographic projection of the isolation opening 510 on the base plate 100, that is, a size of the isolation opening 510 is greater than a size of the pixel opening 230, so that more light-emitting material can fall into the pixel opening 230.

Optionally, the base plate 100 is provided with a first electrode layer 700 including a plurality of first electrodes 710 which are provided at intervals, and an orthographic projection of each of the first electrodes 710 on the base plate 100 at least partially overlaps an orthographic projection of a corresponding pixel opening 230 on the base plate 100, so that the first electrode 710 can drive the light-emitting unit 310 within the pixel opening 230 to emit light. Optionally, the orthographic projection of the pixel opening 230 on the base plate 100 is located within the orthographic projection of the first electrode 710 on the base plate 100, so that a contact area between the light-emitting unit 310 and the first electrode 710 is increased.

Optionally, the display panel further includes a second electrode layer 800, the second electrode layer 800 includes second electrodes 810 respectively located on a side of the light-emitting units 310 away from the base plate 100, and the second electrode 810 and the first electrode 710 may interact with each other to drive the light-emitting unit 310 to emit light. Optionally, a material of the isolation structure 500 includes a conductive material, and the second electrodes 810 are in contact with and connected to the isolation structure 500, so that the second electrodes 810 may be interconnected as an entire electrode by the isolation structure 500.

Optionally, the display panel further includes an encapsulation layer 400 including a first encapsulation layer 410, and the first encapsulation layer 410 includes an encapsulation portion 411 located on a side of a corresponding second electrode 810 away from the base plate 100, so that each of encapsulation portions 411 can seal a corresponding light-emitting unit 310, and an impact of water and oxygen intrusion on the light-emitting effect of the light-emitting unit 310 is reduced.

Optionally, the encapsulation portion 411 is located in the display region AA. The encapsulation layer 400 further includes a second encapsulation layer 420 located on a side of the first encapsulation layer 410 away from the base plate 100, and the second encapsulation layer 420 is in contact with and connected to at least a part of the contact portion 220. A problem can be reduced that the contact area between the first encapsulation layer 410 and the second encapsulation layer 420 is so large that the second encapsulation layer 420 has excessive fluidity, thereby improving the encapsulation performance of the second encapsulation layer 420.

Optionally, the second encapsulation layer 420 and the contact portion 220 both extend to the non-display region NA and are in contact with and connected to each other within the non-display region NA. The first encapsulation layer 410 is located within the display region AA, the second encapsulation layer 420 and the contact portion 220 extend from the first encapsulation layer 410 to be connected to each other.

Optionally, each of the encapsulation portions 411 is located on a side of a corresponding second electrode 810 away from the base plate 100, so that each of the encapsulation portions 411 can provide protection for the corresponding second electrode 810.

Optionally, an orthographic projection of each of the second electrodes 810 on the base plate 100 is located within an orthographic projection of a corresponding encapsulation portion 411 on the base plate 100, that is, a size of the encapsulation portion 411 is greater than a size of the second electrode 810, so that the encapsulation portion 411 can provide better protection for the second electrode 810.

Optionally, an orthographic projection of each of the isolation openings 510 on the base plate 100 is located within the orthographic projection of the corresponding encapsulation portion 411 on the base plate 100, that is, the size of the encapsulation portion 411 is relatively great, and the encapsulation portion 411 may extend to a surface of the isolation structure 500 away from the base plate 100 to provide better encapsulation performance.

Optionally, a gap is provided between adjacent encapsulation portions 411 and is located on a side of the isolation structure 500 away from the base plate 100, that is, a plurality of encapsulation portions 411 are independent from each other.

Optionally, a material of the inorganic layer 200 may include at least one of silicon nitride, silicon oxide, and silicon oxynitride.

Optionally, the inorganic layer 200 is a single film layer, or the inorganic layer 200 includes a plurality of stacked film layers, that is, the inorganic layer 200 may be formed by stacking the plurality of film layers.

Optionally, a film-forming condition for the inorganic layer 200 is above 150° C., films formed in the film-forming condition for the pixel definition layer 200 are more hermetically sealed than films formed in a film-forming condition for the first encapsulation layer 410, and free bonds of the oxygen element are relatively less, so that the overflow of the second encapsulation layer 420 is buffered to a certain extent.

Optionally, a material of the first encapsulation layer 410 includes an inorganic material, that is, a material of each of the encapsulation portions 411 includes an inorganic material, so that each of the encapsulation portions 411 has a desired hermetic sealing, and is able to provide a better hermetic protection for a corresponding light-emitting unit 310.

Optionally, a material of the second encapsulation layer 420 includes an organic material, so that the second encapsulation layer 420 may have a relatively great thickness, and flatness of the whole surface of the encapsulation layer 400 can be adjusted.

In some optional embodiments, the encapsulation layer 400 further includes a third encapsulation layer 430 located on a side of the second encapsulation layer 420 away from the base plate 100, and the third encapsulation layer 430 in the non-display region NA extends from the second encapsulation layer 420 and is in contact with and connected to the contact portion 220.

In these optional embodiments, the encapsulation layer 400 further includes the third encapsulation layer 430, and the third encapsulation layer 430 in the non-display region NA extends from the second encapsulation layer 420, that is, a size of the third encapsulation layer 430 is greater than a size of the second encapsulation layer 420, and the third encapsulation layer 430 is in contact with and connected to the contact portion 220 outside the second encapsulation layer 420, thereby improving the overall sealing performance of the encapsulation layer 400.

Optionally, an edge of an orthographic projection of the second encapsulation layer 420 on the base plate 100 is located on a side of an outer edge of an orthographic projection of the contact portion 220 on the base plate 100 facing to the display region AA. That is, the edge of the contact portion 220 extends from the second encapsulation layer 420 along a direction from the display region AA to the non-display region NA, and the contact portion 220 may be hermetically connected to the third encapsulation layer 430 outside the second encapsulation layer 420. That is, one part of the contact portion 220 is in contact with and connected to the second encapsulation layer 420, and the other part of the contact portion 220 is in contact with and connected to the third encapsulation layer 430, so that a contact area between the contact portion 220 and the second encapsulation layer 420 and the third encapsulation layer 430 can be increased, and the sealing effect of the encapsulation layer 400 is further improved.

Optionally, the orthographic projection of the second encapsulation layer 420 on the base plate 100 is located within an orthographic projection of the third encapsulation layer 430 on the base plate 100. That is, the size of the third encapsulation layer 430 is greater than the size of the second encapsulation layer 420, and the third encapsulation layer 430 can provide a longer sealing length, so that the sealing effect of the encapsulation layer 400 is further improved.

Optionally, a material of the third encapsulation layer 430 includes an inorganic material, so that the third encapsulation layer 430 has a better sealing effect, thereby improving the overall sealing performance of the encapsulation layer 400.

Optionally, the second encapsulation layer 420 is located on a side of the dam 110 facing to the display region AA, and the contact portion 220 and the third encapsulation layer 430 extend to a side of the dam 110 away from the display region AA.

In these optional embodiments, the second encapsulation layer 420 is located on a side of the dam 110 facing to the display region AA, the second encapsulation layer 420 is limited by the dam 110 in a region where the dam 110 is enclosed and formed, and the third encapsulation layer 430 and the contact portion 220 extend to a side of the dam 110 away from the display region AA, that is, the third encapsulation layer 430 and the contact portion 220 extend to an outer side of the dam 110, so that the encapsulation length can be increased, and the encapsulation yield is improved.

Optionally, in a region where the dam 110 is located, the contact portion 220 is in contact with the third encapsulation layer 430, that is, the contact portion 220 and the third encapsulation layer 430 are connected on a side of the dam 110 away from the base plate 100, and the dam 110 is generally relatively high, so that a segment gap can be increased because of the dam 110. The contact portion 220 is in contact with and connected to the third encapsulation layer 430 at a location with a relatively great segment gap, so that the encapsulation yield can be further improved.

The isolation structure 500 may be provided in various manners, for example, the isolation structure 500 is a single-layer structure and includes a first surface facing to the base plate 100 and a second surface away from the base plate 100, and an orthographic projection of the first surface on the base plate 100 is located within an orthographic projection of the second surface on the base plate 100. That is, a size of the first surface is less than a size of the second surface, so that a concave structure may be formed under the second surface, and under a condition that the light-emitting unit 310 is manufactured subsequently, the light-emitting material is partitioned into a plurality of independent light-emitting units 310 on an edge of the second surface.

Optionally, in other embodiments, the isolation structure 500 includes a first layer 520 and a second layer 530 which are stacked, the second layer 530 is located on a side of the first layer 520 away from the base plate 100, and an orthographic projection of the first layer 520 on the base plate 100 is located within an orthographic projection of the second layer 530 on the base plate 100. That is, a size of the first layer 520 is less than a size of the second layer 530, so that a concave structure may be formed under the second layer 530, and under a condition that the light-emitting unit 310 is manufactured subsequently, the light-emitting material is partitioned into a plurality of independent light-emitting units 310 on an edge of the second layer 530.

Optionally, a material of the first layer 520 includes a conductive material and is in contact with and connected to the second electrodes 810, so that a plurality of second electrodes 810 may be interconnected as an entire electrode by the first layer 520.

Optionally, a material of the second layer 530 includes a conductive material, and the material of the second layer 530 is different from the material of the first layer 520. In these optional embodiments, the material of the second layer 530 includes the conductive material, so that a distribution area of the conductive structure can be increased, and the overall resistance of the second electrodes 810 can be decreased. The material of the second layer 530 is different from the material of the first layer 520, so that the first layer 520 and the second layer 530 with different sizes are formed using different etching rates under a condition that different materials react with the same etching solution.

Optionally, the isolation structure 500 further includes a third layer 540 located on a side of the first layer 520 facing to the base plate 100, the orthographic projection of the first layer 520 on the base plate 100 is located within an orthographic projection of the third layer 540 on the base plate 100. Under a condition that the isolation structure 500 is formed by performing a side etching on the first layer 520, the third layer 540 may have a protection effect to reduce the impact of etching on a film layer on a side of the third layer 540 facing to the base plate 100.

In any of the above embodiments, a relative positional relationship between the isolation structure 500 and the inorganic layer 200 may be various, for example, the isolation structure 500 may be located on a side of the inorganic layer 200 away from the base plate 100, or the isolation structure 500 may be located on a side of the pixel definition portion 210 away from the base plate 100. Optionally, the pixel definition portion 210 is provided with an accommodation opening, and the isolation structure 500 may be located in the accommodation opening, and may be in direct contact with and connected to the base plate 100.

The embodiments of the first aspect of the present application further provide a display panel having a display region AA and a non-display region NA provided around at least a part of the display region AA, and the display panel includes: a base plate 100; a dam 110 provided on a side of the base plate 100 and provided around the display region AA in the non-display region NA, wherein the dam 110 includes a first organic layer 111; and an inorganic layer 200 provided on a side of the dam 110 away from the base plate 100, wherein the inorganic layer 200 is provided with a first via 240 extending through the inorganic layer 200, and the first via 240 exposes at least a part of a region of the first organic layer 111.

In the embodiments of the present application, the first via 240 exposes at least a part of a region of the first organic layer 111, that is, at least a part of the first organic layer 111 can be exposed by the first via 240, and the gas generated in the first organic layer 111 may leak out through the first via 240, thereby reducing a problem of peeling-off easily caused by the presence of gas between the first organic layer 111 and the inorganic layer 200.

The embodiments of the first aspect of the present application further provide a display panel having a display region AA and a non-display region NA provided around at least a part of the display region AA, and the display panel includes: a base plate 100; a dam 110 provided on the base plate 100 and provided around the display region AA in the non-display region NA, wherein the dam 110 includes a first organic layer 111; and a pixel definition layer provided on the base plate 100 and including a pixel definition portion 210 located in the display region AA and a contact portion 220 located in the non-display region NA, wherein the pixel definition portion 210 is provided with a plurality of pixel openings 230; wherein at least a part of the contact portion 220 covers the dam 110, the contact portion 220 is provided with a first via 240, and an orthographic projection of the first via 240 on the base plate 100 overlaps an orthographic projection of the first organic layer 111 on the base plate 100.

In these optional embodiments, the display panel includes the base plate 100, the dam 110, and the pixel definition layer. The dam 110 is provided around the display region AA, and is configured to define a position of an encapsulation material of the organic encapsulation layer 400. The pixel definition layer includes the pixel definition portion 210 and the contact portion 220, and the pixel definition portion 210 is provided with the pixel opening 230 to accommodate the light-emitting unit 310, so that the display panel emits light and displays. The contact portion 220 covers the dam 110, and the contact portion 220 is provided with the first via 240, so that the gas generated in the first organic layer 111 flows out, thereby reducing a problem of peeling-off that occurs easily between the contact portion 220 and the first organic layer 111.

Optionally, a material of the pixel-definition layer includes an inorganic material, and the pixel-definition layer may be provided in the same manner as the above inorganic layer 200.

Optionally, the base plate 100 and the dam 110 are provided as described above, which is not repeated herein.

Relevant technical solutions such as the isolation structures are recited in patents 202311117143.6, 202310759370.2, 202310771124.9, 202311499823.9, 202310731471.9, 202410008807.3, 202311091555.7 and 202310707209.0, and contents thereof are incorporated into the present application by reference, and are not repeated in the present embodiment.

Embodiments of a second aspect of the present application provide a display apparatus including the display panel according to any of the embodiments of the first aspect. Since the display apparatus according to the embodiments of the second aspect of the present application includes the display panel according to any of the embodiments of the first aspect, the display apparatus according to the embodiments of the second aspect of the present application has the beneficial effects of the display panel according to any of the embodiments of the first aspect, which is not repeated herein.

The display apparatus according to the embodiments of the present application includes, but is not limited to a mobile phone, a personal digital assistant (PDA), a tablet computer, e-book, a television, an access control, a smart fixed phone, a console and other devices with a display function.

Although the present application has been described with reference to the preferred embodiments, various modifications can be made thereto and components thereof can be replaced with their equivalents without departing from the scope of the present application. In particular, various technical features described in various embodiments can be combined in any manner as long as there is no structural conflict. The present application is not limited to the specific embodiments described herein, and includes all technical solutions that fall within the scope of the claims.

What is claimed is:

1. A display panel, comprising:
a base plate;
at least a dam, provided on a side of the base plate and comprising a first organic layer; and
an inorganic layer, provided on a side of the dam away from the base plate and in contact with and connected to the first organic layer, wherein the inorganic layer is provided with a first via extending through the inorganic layer, and an orthographic projection of the first via on the base plate overlaps an orthographic projection of the first organic layer on the base plate.

2. The display panel according to claim 1, wherein
the orthographic projection of the first via on the base plate is located within the orthographic projection of the first organic layer on the base plate.

3. The display panel according to claim 1, further comprising:
a first conductive line, provided on a side of the first organic layer facing to the base plate, wherein the first conductive line is provided with a second via extending through the first conductive line, the first via comprises a first sub-via, and an orthographic projection of the first sub-via on the base plate at least partially overlaps an orthographic projection of the second via on the base plate.

4. The display panel according to claim 3, wherein the orthographic projection of the second via on the base plate is located within an orthographic projection of the dam on the base plate.

5. The display panel according to claim 4, wherein the orthographic projection of the first sub-via on the base plate is located within the orthographic projection of the second via on the base plate.

6. The display panel according to claim 3, wherein orthographic projections of a plurality of the first sub-vias on the base plate are located within an orthographic projection of a same dam on the base plate; and
the plurality of the first sub-vias are provided at intervals along an extension direction of the dam.

7. The display panel according to claim 3, wherein the display panel comprises a plurality of the first sub-vias and a plurality of the second vias, the plurality of the first sub-vias and the plurality of the second vias are in a one-to-one correspondence, and an orthographic projection of each of the first sub-vias is located within an orthographic projection of a corresponding second via of the plurality of the second vias.

8. The display panel according to claim 7, wherein the first conductive line comprises a power signal line; and
the inorganic layer covers an inner wall surface of the first conductive line facing to the second via.

9. The display panel according to claim 3, wherein the first via further comprises a second sub-via, and an orthographic projection of the second sub-via on the base plate is located outside an orthographic projection of the first conductive line on the base plate.

10. The display panel according to claim 9, wherein a length of the second sub-via along an extension direction of the dam is greater than a length of the first sub-via along the extension direction of the dam.

11. The display panel according to claim 9, wherein an area of the orthographic projection of the second sub-via on the base plate is greater than an area of the orthographic projection of the first sub-via on the base plate; and
the second sub-via extends and is formed along the extension direction of the dam.

12. The display panel according to claim 1, wherein the display panel comprises a display region and a non-display region provided around the display region, the dam is located in the non-display region, the inorganic layer comprises a pixel definition layer comprising a pixel definition portion located in the display region and a contact portion located in the non-display region, the first via is provided in the contact portion, and the pixel definition portion is provided with a plurality of pixel openings; and
a light-emitting unit is provided in the pixel opening.

13. The display panel according to claim 12, further comprising:
an isolation structure provided on the base plate,
an isolation opening surrounded by the isolation structure,
wherein an orthographic projection of the isolation opening on the base plate at least partially overlaps an orthographic projection of the pixel opening on the base plate.

14. The display panel according to claim 13, wherein the isolation structure is located on a side of the pixel definition layer away from the base plate, or the pixel definition portion is provided with an accommodation opening, and the isolation structure is provided in the accommodation opening.

15. The display panel according to claim 13, wherein the isolation structure comprises a first layer and a second layer located on a side of the first layer away from the base plate, and an orthographic projection of the first layer on the base plate is located within an orthographic projection of the second layer on the base plate; and
a material of the first layer comprises a conductive material.

16. The display panel according to claim 15, wherein the isolation structure further comprises a third layer located on a side of the first layer facing to the base plate, and the orthographic projection of the first layer on the base plate is located within an orthographic projection of the third layer on the base plate, or the orthographic projection of the first layer on the base plate overlaps the orthographic projection of the third layer on the base plate.

17. The display panel according to claim 1, wherein the display panel comprises a display region and a non-display region provided around the display region, the at least a dam comprises a plurality of the dams provided in sequence along a direction from the display region to the non-display region, and each of the dams comprises the first organic layer.

18. A display panel, wherein the display panel has a display region and a non-display region provided around at least a part of the display region, and the display panel comprises:
a base plate;
a dam provided on a side of the base plate and provided around the display region in the non-display region, wherein the dam comprises a first organic layer; and
an inorganic layer provided on a side of the dam away from the base plate, wherein the inorganic layer is provided with a first via extending through the inorganic layer, and the first via exposes at least a part of a region of the first organic layer.

19. A display panel, wherein the display panel has a display region and a non-display region provided around at least a part of the display region, and the display panel comprises:
a base plate;
a dam provided on a side of the base plate and provided around the display region in the non-display region, wherein the dam comprises a first organic layer; and
a pixel definition layer provided on a side of the base plate and comprising a pixel definition portion located in the display region and a contact portion located in the non-display region, wherein the pixel definition portion is provided with a plurality of pixel openings;
wherein at least a part of the contact portion covers the dam, the contact portion is provided with a first via, and an orthographic projection of the first via on the base plate overlaps an orthographic projection of the first organic layer on the base plate.

20. A display apparatus, comprising the display panel according to claim 1.
